(19) United States
(12) Patent Application Publication
(10) Pub. No.: US 2025/0198748 A1
(43) Pub. Date: Jun. 19, 2025

(54) METHOD OF MEASURING EDGE ECCENTRICITY WHILE WAFER IS ON PRE-ALIGNER

(71) Applicant: CANON KABUSHIKI KAISHA, Tokyo (JP)

(72) Inventors: Logan L. Simpson, Coupland, TX (US); Byung-Jin Choi, Austin, TX (US); Tom H. Rafferty, Austin, TX (US); Humberto BOCANEGRA EVANS, Austin, TX (US)

(21) Appl. No.: 18/541,810

(22) Filed: Dec. 15, 2023

(51) Int. Cl. G01B 11/24; H01L 21/66; H01L 21/68

(52) U.S. Cl. CPC G01B 11/24; H01L 21/681; H01L 22/12

(57) ABSTRACT

A method of determining a boundary of a substrate on a pre-aligner, the method including loading the substrate with a film onto the pre-aligner, measuring a substrate edge of the substrate, determining a substrate center of the substrate based on the substrate edge, measuring a film edge of the film on the substrate and determining a film edge shape of the film edge relative to the substrate center based on the measurements of the film edge.

### BACKGROUND

### Field of Art

The present disclosure relates to a method of measuring edge eccentricity while a semiconductor wafer is on a pre-aligner for generating drop patterns for imprint lithography and inkjet-based adaptive planarization, in particular, the method is directed to determining a boundary of a field on the semiconductor wafer to be imprinted to generate a cropped drop pattern.

### Description of the Related Art

Nano-fabrication includes the fabrication of very small structures that have features that are 100 nanometers or smaller. One application of nano-fabrication is the fabrication of integrated circuits. The semiconductor-processing industry continues to strive for larger production yields while increasing the circuits per unit area formed on a substrate. Improvements in nano-fabrication include providing greater process control and increasing throughput while also allowing continued reduction of the minimum feature dimensions of the structures formed.

Some nano-fabrication techniques are commonly referred to as nanoimprint lithography. Nanoimprint lithography is useful in a variety of applications including, for example, fabricating one or more layers of integrated devices. Examples of integrated devices include CMOS logic, microprocessors, NAND Flash memory, NOR Flash memory, DRAM memory, MRAM, 3D cross-point memory, Re-RAM, Fe-RAM, STT-RAM, MEMS, and the like.

Some nanoimprint lithography techniques form a feature pattern in a formable material (polymerizable) layer and transfer a pattern corresponding to the feature pattern into or onto an underlying substrate. The patterning process uses a template spaced apart from the substrate, and a formable liquid is applied between the template and the substrate. The formable liquid is solidified to form a solid layer that has a pattern conforming to a shape of the surface of the template that is in contact with the formable liquid. After solidification, the template is separated from the solidified layer such that the template and the substrate are spaced apart. The substrate and the solidified layer are then subjected to additional processes, such as etching processes, to transfer a relief image into or onto the substrate that corresponds to the pattern in the solidified layer.

Additionally, planarization techniques are useful in fabricating semiconductor devices. For example, the process for creating a semiconductor device may include repeatedly adding and removing material to and from a substrate. This process can produce a layered substrate with an irregular height variation (i.e., relief pattern), and, as more layers are added, the substrate's height variation can increase. The height variation negatively affects the ability to add further layers to the layered substrate. Moreover, semiconductor substrates (e.g., silicon wafers) themselves are not always perfectly flat and may include an initial surface height variation (i.e., relief pattern). One technique to address height variations is to planarize the substrate between layering procedures. A planarization technique sometimes referred to as inkjet-based adaptive planarization (IAP) involves dispensing a variable drop pattern of polymerizable material between the substrate and a superstrate, where the drop pattern varies depending on the substrate's relief pattern. A superstrate is then brought into contact with the polymerizable material, after which the material is polymerized on the substrate, and the superstrate removed.

The material on the semiconductor wafer may also be described as a film layer. The eccentricity of film layers on semiconductor wafers must be considered when generating drop patterns for imprinting. Erroneous drop patterns risk mask damage, transfer defects and large stage alignment forces during overlay. Each semiconductor wafer is unique and must be measured to determine film layer eccentricity so that customized drop patterns can be generated.

In order to ensure performance when imprinting of a semiconductor wafer, it is necessary to know where the boundary of the underlying field is. This is required for cropping drop patterns on the field. The boundaries are not consistent from wafer to wafer. One well known method for determining the boundary of a field is to measure the boundary using a one tool microscope. Manually using a microscope to get the stage location of the semiconductor wafer edge and of the film layer edge points around the semiconductor wafer perimeter. Entering the data into a spreadsheet to calculate the center offsets. Then the drop patterns are cropped to account for the eccentricity of the film layer on the semiconductor wafer. However, this method is a time intensive process and has a significant impact on throughput. Another well known method is to use a bevel edge inspection tool. However, the bevel edge inspection tool is not designed for layer edge measurement and tends to be noisy. The manual method is accurate, but very time consuming. The bevel edge inspection tool is fast but not sufficiently accurate for finely customized drop patterns.

Measurement of film edge eccentricity is either time intensive or low accuracy. There is a need in the art for a method of measuring film edge eccentricity while the semiconductor wafer is on a pre-aligner to measure a center of the semiconductor wafer. There is also a need to adjust the drop pattern based on eccentricity or boundary that is determined on the pre-aligner.

### SUMMARY

The present disclosure is directed to boundary imaging using a camera on a semiconductor wafer pre-aligner, using software to analyze and determine a boundary and semiconductor wafer edge to generate a drop pattern with matching edge trim per partial field in imprint lithography or the whole semiconductor wafer in inkjet-based adaptive planarization.

The present disclosure is directed to a method of determining a boundary of a substrate on a pre-aligner. The method includes loading the substrate with a film onto the pre-aligner, then measuring a substrate edge of the substrate. The method continues with determining a substrate center of the substrate based on the substrate edge, measuring a film edge of the film on the substrate and determining a film edge shape of the film edge relative to the substrate center based on the measurements of the film edge.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure, and are therefore not to be considered limiting of its scope, for the disclosure may admit to other equally effective embodiments.

FIG. 1 is an illustration of an exemplary nanoimprint lithography system in accordance with an example embodiment.

FIGS. 2A-B are illustrations of exemplary templates that may be used in an embodiment.

FIG. 3 is a flowchart illustrating an exemplary imprinting method as used in an embodiment.

FIG. 4 is an illustration of a layout of fields on substrates as used in an embodiment.

FIG. 5 illustrates a pre-aligner in accordance with an example embodiment of the present disclosure.

FIG. 6 shows a top view of a semiconductor wafer with a film layer in accordance with an example embodiment.

FIG. 7 shows a top view of a semiconductor wafer from FIG. 6 with an additional film layer in accordance with an example embodiment.

FIG. 8 shows a top view of a semiconductor wafer with a patterned layer including full fields and partial fields for nanoimprint lithography in accordance with an example embodiment.

FIG. 9 shows a top view of the semiconductor wafer from FIG. 8 with an edge cut boundary in accordance with an example embodiment.

FIG. 10 shows a zoomed-in side view of a substrate illustrating an edge cut associated with an edge bead removal (EBR) process.

FIG. 11 is a flowchart illustrating an exemplary method for generating cropped drop patterns in accordance with an example embodiment.

FIG. 12 shows a full field drop pattern and a cropped partial field drop pattern, in accordance with an example embodiment.

FIG. 13 shows a full field pattern plotted on the semiconductor wafer, in accordance with an example embodiment.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

Throughout this disclosure, reference is made primarily to nanoimprint lithography, which uses a patterned template to impart a pattern onto formable liquid. However, as mentioned below, in an alternative embodiment, the template is featureless in which case a planar surface may be formed on the substrate. In such embodiments where a planar surface is formed, the formation process is referred to as planarization. Thus, throughout this disclosure, whenever nanoimprint lithography is mentioned, it should be understood that the same method is applicable to planarization. The term superstrate is used in place of the term template in instances where the template is featureless.

The present disclosure relates to an integrated, on-tool, eccentricity measurement system of imprint lithography. The eccentricity of film layers on wafers are considered when generating drop patterns for partial field imprinting. Erroneous drop patterns risk mask damage, transfer defects and large stage alignment forces during overlay. Each wafer is unique and must be measured to determine the layer eccentricity so that customized drop patterns can be created. Measuring each wafer is time consuming. The present disclosure is directed to an automated, fast, on-tool system to do the required measurements. The present disclosure integrates a camera system into the wafer pre-aligner which will detect the location of the wafer edge and of the film edge while the wafer is spinning during the pre-align step. The images will be analyzed to calculate the eccentricity of the film(s), custom partial field drop patterns will be generated while the wafer is completing the load process. Other lithography equipment can also use a pre-aligner that also measures eccentricity of film layers on a substrate while determining a center and orientation of a substrate.

The nanoimprint lithography technique can be used in a step and repeat manner to shape a film with a template in a plurality of fields across a substrate. The substrate and a patterning area (mesa) of a template may have different shapes and sizes. For example, the substrate may have a region to be patterned that is circular, elliptical, polygonal, or some other shape. While the mesa is typically smaller than the substrate and has a different shape than the substrate. The substrate is divided into a plurality of full fields and a plurality of partial fields. The full fields are the same size as the mesa. The partial fields are those fields on the edge of the substrate in which the edge of the region to be patterned on the substrate intersects with the patterning on the mesa. These fields may be divided into multiple categories based on their shape and/or area relative to the full field.

The partial fields tend to have higher defectivity and/or higher processing time then full fields. In addition, small partial fields which have an area less than 30% of a full field are particularly challenging. What is needed is a way to lower defectivity and/or higher processing time for small partial fields.

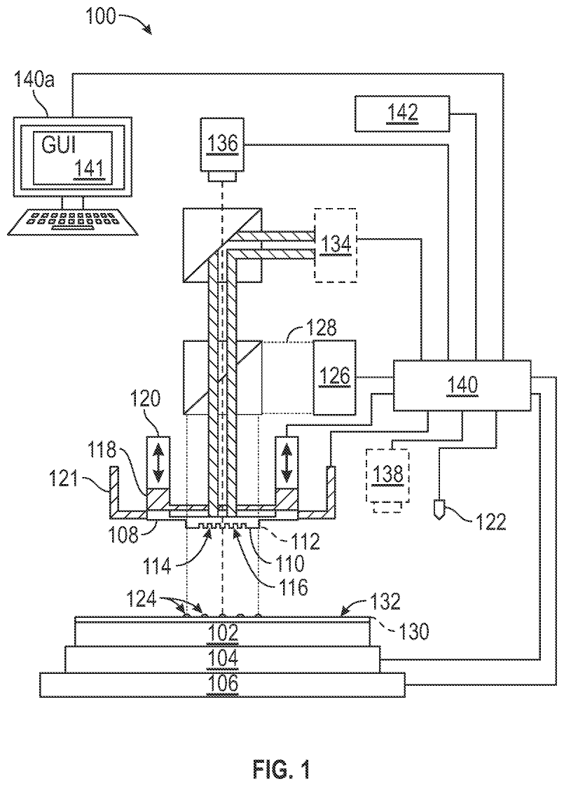

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x, y, z, θ, and φ-axes. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa (also referred to as a mold) 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The shaping surface 112 may have features defined by a plurality of spaced-apart template recesses 114 and/or template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

Template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include a template magnification control system 121. The template magnification control system 121 may include piezoelectric actuators (or other actuators) which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g., positional axes x, and y, and rotational axes θ, ψ, and φ).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the shaping surface 112 and the substrate 102 depending on design considerations. The formable material 124 may comprise a mixture including a monomer as described in U.S. Pat. No. 7,157,036 and U.S. Pat. No. 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 128. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has contacted the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as lenses, mirrors, optical diaphragms, apertures, filters, prisms, polarizers, windows, adaptive optics, and/or light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124.

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 128. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer. In another embodiment, the substrate 102 may be a blank template (replica blank) that may be used to create a daughter template after being imprinted. In another embodiment, the substrate is a blank superstrate.

The shaping system 100 may include an imprint field atmosphere control system such as gas and/or vacuum system, an example of which is described in U.S. Patent Publication Nos. 2010/0096764 and 2019/0101823 which are hereby incorporated by reference. The gas and/or vacuum system may include one or more of pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 may be regulated, controlled, and/or directed by one or more processors 140 (controller) in communication with one or more components and/or subsystems such as the substrate chuck 104, the substrate positioning stage 106, the template chuck 118, the shaping head 120, the fluid dispenser 122, the radiation source 126, the thermal radiation source 134, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100a and in communication with the shaping system 100a. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator and/or user.

Either the shaping head 120, the substrate positioning stage 106, or both varies a distance between the mold 110 and the substrate 102 to define a desired space (a bounded physical extent in three dimensions) that is filled with the formable material 124. For example, the shaping head 120 may apply a force to the template 108 such that mold 110 is in contact with the formable material 124. After the desired volume is filled with the formable material 124, the radiation source 126 produces actinic radiation (e.g., UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the imprint fields may be the same size as the mesa 110 or just the pattern area of the mesa 110. The pattern area of the mesa 110 is a region of the shaping surface 112 which is used to imprint patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field which is the same size as the substrate 102 or the area of the substrate 102 which is to be patterned with the mesa 110. In an alternative embodiment, the imprint fields overlap. Some of the imprint fields may be partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

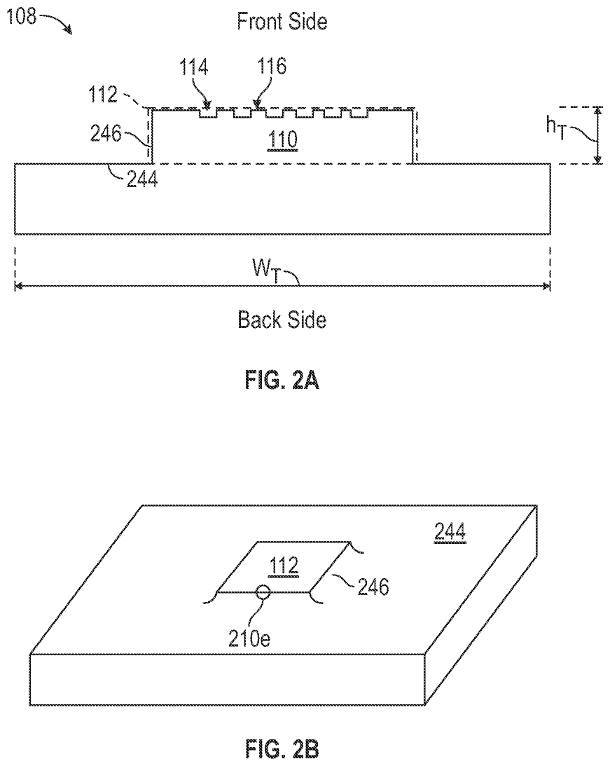

FIG. 2A is an illustration of a template 108 (not to scale) that may be used in an embodiment. The shaping surface 112 may be on a mesa 110 (identified by the dashed box in FIG. 2A). The mesa 110 is surrounded by a recessed surface 244 on the front side of the template. The mesa 110 has a mesa height h_{T}. The mesa height h_{T} may between 1-200 μm. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles. FIG. 2B is a perspective view of the template 108 (not to scale) showing the mesa edges 210e. FIG. 2B illustrate that the intersection of the mesa sidewalls 246 and the recessed surface 244 may have some curvature due to the process of etching away material from a template precursor to form the mesa 110 on the template 108. The template 108 may have a square planar shape with a template width W_{T} as illustrated in FIGS. 2A-B. In an alternative embodiment, the template width W_{T} is a characteristic width and a planar shape of the template 108 may be a rectangle, parallelogram, polygon, or circle, or some other shape. The template width W_{T} may be between 10-200 mm.

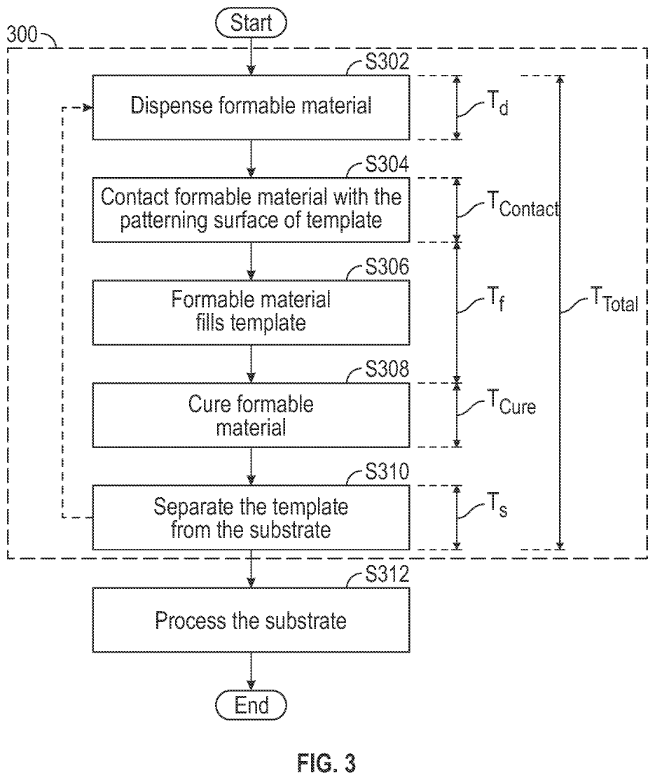

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈Z⁺}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period Td for each imprint field i.

In an embodiment, during the dispensing step S302, the formable material 124 is dispensed onto the substrate 102 in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period Tcontact which starts after the dispensing period Td and begins with the initial contact of the shaping surface 112 with the formable material 124. In an embodiment, at the beginning of the contact period Tcontact the template chuck 118 is configured to bow out the template 108 so that only a portion of the shaping surface 112 is in contact with a portion of the formable material. In an embodiment, the contact period Tcontact ends when the template 108 is no longer bowed out by the template chuck 118. The degree to which the shaping surface 112 is bowed out relative to the substrate surface 130 may be estimated with the spread camera 136. The spread camera 136 may be configured to record interference fringes due to reflectance from at least the shaping surface 112 and the substrate surface 130. The greater the distance between neighboring interference fringes, the larger the degree to which the shaping surface 112 is bowed out.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period Tf. The filling period Tf begins when the contacting step S304 ends. The filling period Tf ends with the start of a curing period Tc. In an embodiment, during the filling period Tf the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period Tc. The curing illumination pattern provides enough energy to cure (polymerize) the formable material 124 under the shaping surface 112. The curing period Tc is a period in which the formable material under the template receives actinic radiation with an intensity that is high enough to solidify (cure) the formable material. In an alternative embodiment, the formable material 124 is exposed to a gelling illumination pattern of actinic radiation before the curing period Tc which does not cure the formable material but does increase the viscosity of the formable material.

In a separation step S310, the processor 140 uses one or more of: the substrate chuck 104; the substrate positioning stage 106, template chuck 118, and the shaping head 120 to separate the shaping surface 112 of the template 108 from the cured formable material on the substrate 102 during a separation period Ts. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g., semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

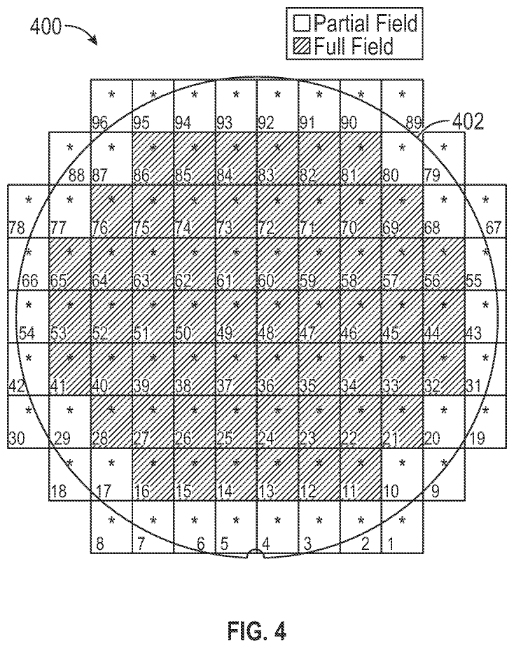

The shaping process 300 can be used in a step and repeat manner to shape a film with a template 108 in a plurality of fields across the substrate 102. The substrate 102 and a patterning area (mesa 110) of a template 108 may have different shapes and sizes. For example, the substrate 102 may have a region to be patterned that is circular, elliptical, polygonal, or some other shape. While the mesa 110 is typically smaller than the substrate 102 and has a different shape than the substrate 102. The substrate 102 is divided into a plurality of full fields and a plurality of partial fields as illustrated in FIG. 4. The full fields are the same size as the mesa 110. The partial fields are those fields on the edge of the substrate in which the edge of the region to be patterned on the substrate intersects with the patterning area of the mesa. These fields may be divided into multiple categories based on their shape and/or area relative to the full field.

FIG. 4 is an illustration of partial fields and full fields on a substrate 400. In one embodiment, the substrate 400 is a semiconductor wafer. The substrate 400 shown in FIG. 4 includes 96 different fields labeled from 1 to 96. The substrate edge 402 represents the perimeter or edge of the semiconductor wafer. The fields that intersect with the substrate edge 402 are known as partial fields. The partial fields in this example include fields 1-10, 17-20, 29-31, 42, 43, 54, 55, 66-68, 77-80, 87-96. The substrate 400 may also have undergone numerous previous processes which cause the edge to have a random unpredictable pattern. The substrate 400 may also have an orientation feature such as a notch or flat edge.

The present disclosure determines shot center locations of each field of the substrate 400 in an X, Y coordinate system. The center locations are determined by software according to the present disclosure and discussed below while the substrate 400 or semiconductor wafer is on a pre-aligner. Determining the center locations enables generating a cropped drop pattern for the formable material.

For full fields, the initial contact point is at the center of the full field. While the initial contact point is a single point the actual initial contact area is a larger area which may have an area of for example of 1 to 2 mm² when 0.1 N of imprint force is detected during the initial contact. For partial fields, determining the initial contact point is more complicated which depends on the shape and area of the partial field. For large partial fields (90% to 99% of the full field) the initial contact point may be at the same point as the full field or somewhere within the initial contact area. For medium size partial fields, the initial contact point may be determined by calculating a geometric center (GC) or a centroid of the partial field. There are several methods that may be used for determining the GC. One method of estimating the GC is to use a method of intersecting meridians. Another method is to approximate the edge of the partial field using a function. The function may be defined in a piecewise manner and be continuous over the partial field. Integration may then be used to estimate a geometric center of the partial field. A third method of identifying the GC is to minimize distances from the GC to the farthest corners of the partial field.

Generating a drop pattern for a full field may include a processor 140 receiving a substrate pattern of a representative substrate 102, and a template pattern of a representative template 108.

The substrate pattern may include information about substrate topography of the representative substrate, a field of the representative substrate and/or a full field of the representative substrate. The substrate topography may be measured, generated based on previous fabrication steps and/or generated based on design data. In an alternative embodiment, the substrate pattern is featureless either because there were no previous fabrication steps or the substrate had previously been planarized to reduce topography. The substrate topography may include information about the shape of an edge such as a beveled edge or a rounded edge of the representative substrate. The substrate topography may include information about the shape and position of one or more flats or notches which identify the orientation of the substrate. The substrate topography may include information about a shape and position of a reference edge which surrounds the area of the substrate on which patterns are to be formed.

The template pattern may include information about the topography of the patterning surface 112 of the representative template. The topography of the patterning surface 112 may be measured and/or generated based on design data. In an alternative embodiment, the template pattern of the representative embodiment is featureless and may be used to planarize the substrate 102. The patterning surface 112 may be the same size as: an individual full field; multiple fields; the entire substrate, or larger than the substrate.

Once the substrate pattern and the template pattern are received, a processor 140 may calculate a distribution of formable material 124 that will produce a film that fills the volume between the substrate and the patterning surface when the substrate and the patterning surface are separated by a gap during imprinting. The distribution of formable material on the substrate may take the form of: an areal density of formable material; positions of droplets of formable material; and/or volume of droplets of formable material. Calculating the distribution of formable material may take into account one or more of: material properties of the formable material; material properties of the patterning surface; material properties of the substrate surface; spatial variation in volume between the patterning surface and the substrate surface; fluid flow; evaporation; etc.

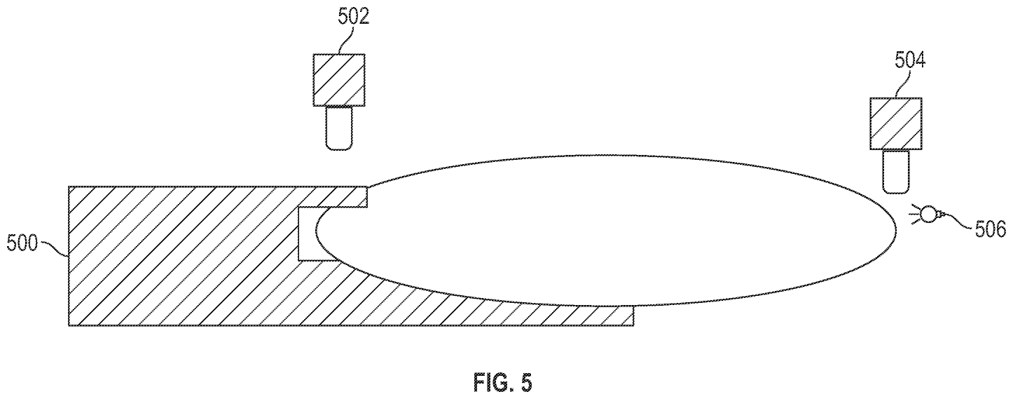

In the present disclosure, the term substrate may be used interchangeably with wafer or semiconductor wafer. During a wafer load process, the wafer is placed onto a pre-aligner chuck and then rotated to locate the wafer orientation feature such as a notch or flat, and a wafer center. While the wafer is rotating, high resolution images of the wafer edge/film layer edge are captured in parallel with the pre-align process. The images need to have sufficient resolution (˜10 μm) so that subsequent image processing steps can accurately locate the wafer edge and the film layer edge. Typically 12 locations around the wafer edge is preferred to calculate eccentricity with acceptable accuracy. Referring now to FIG. 5, a pre-aligner 500 for the semiconductor wafer is shown. A pre-aligner is a standard tool that is used in a semiconductor fabrication plant. The pre-aligner includes at least: a spindle, a chuck, and a sensor system. A substrate is mounted on the chuck and is rotated by a spindle. The sensor system gathers information about the edge of the substrate as the chuck is rotated by the spindle. The sensor system may be an optical system with a light source on one side of the substrate near the edge of the substrate and an optical sensor on the other side of the substrate also near the edge of the wafer held by a chuck that is rotated by the spindle. The optical sensor may include a line sensor. Other types of sensors (for example, capacitive, electrostatic, ultrasonic, etc.) well known in the art may also be used to measure the edge of the wafer and location of the alignment feature (notch or flat) in the substrate on the spindle. The pre-aligners find the center and orientation of a substrate (semiconductor wafer), and remove the decentering variation, and orientation variation of the substrate to provide a substrate handline robot with a repeatedly aligned and oriented substrate which can then be loaded precisely onto other equipment. Some models of pre-aligners will use the substrate center information to remove the substrate decentering with respect to the spindle of the pre-aligner holding the substrate by physically moving the chuck relative to the spindle of the pre-aligner. Other models will modify the robot end effector pick-up location so that the decentering variation is removed once the substrate is picked up. In either case, the orientation (rotation angle) of the substrate is set before the end effector picks up the substrate. The pre-aligner may be part of Equipment Front-End Module (EFEM) or may be a separate pre-aligner. An example of such an EFEM is a RSC141, an example of a pre-aligner is model number RA320-C22-L, both from the Rorze Corporation of Fukuyama-shi, Hiroshima-ken, Japan. Another example of an EFEM is Performix, an example of a pre-aligner is the Dual Axis Single CCD Pre-Aligner, both from Kensington Laboratories, LLC of Dublin, CA. The pre-aligner 500 includes a sensor such as a camera 502 with an illumination source. In the present disclosure an additional camera 504 and illumination source 506 are additional hardware of the pre-aligner 500. In a preferred embodiment, the camera 504 may be a line-scan camera. The illumination source 506 may be a high-powered LED or laser for illuminating the wafer on the pre-aligner 500 as it rotates so that high resolution images are captured using the line-scan camera 504. The line-scan camera 504 is preferably configured to scan up to 500 mm/s. The 500 mm/s scan speed may enable a scan time of less than 2 seconds for a 360 degree rotation of the pre-aligner 500. The line-scan camera 504 scanning speed should be balanced with the pre-aligner speed. The semiconductor wafer is loaded onto the pre-aligner 500 with 0.1 mm accuracy. The semiconductor wafer placement on the pre-aligner 500 includes slight inaccuracies due to robot loading and unloading of the semiconductor wafer on and off the pre-aligner 500. The pre-aligner 500 rotates the wafer to identify the center of the wafer as well as the location of the orientation feature such as the alignment notch. The pre-aligner 500 may include other sensors beside the camera specifically for finding the wafer orientation feature and the center of the wafer. The present disclosure is not limited to one or two line-scan camera 504. Other embodiments of the present disclosure may include additional line-scan cameras with the pre-aligner to inspect a film on the semiconductor wafer to measure the film edge relative to the center of the semiconductor wafer.

The line-scan camera 504 is integrated with the pre-aligner 500 to detect the location of the wafer edge and the film edge relative to the wafer edge while the wafer is spinning during the pre-align process. During the wafer load process, the wafer is placed onto a pre-aligner chuck and then rotated to locate the wafer notch and wafer center. Since the wafer is rotating, the line-scan camera 504 is used to capture high resolution information such as images of the wafer film edge in parallel with the pre-align process. The information (images) from the line-scan camera 504 needs to have sufficient resolution so that the subsequent image processing steps may accurately locate the wafer edge and the film layer edge. In one embodiment, twelve images corresponding to twelve different locations around the wafer edge are required to calculate the eccentricity of the wafer with acceptable accuracy. Twelve images are merely a suggested example and other embodiments of the present disclosure may require less than or greater than twelve images.

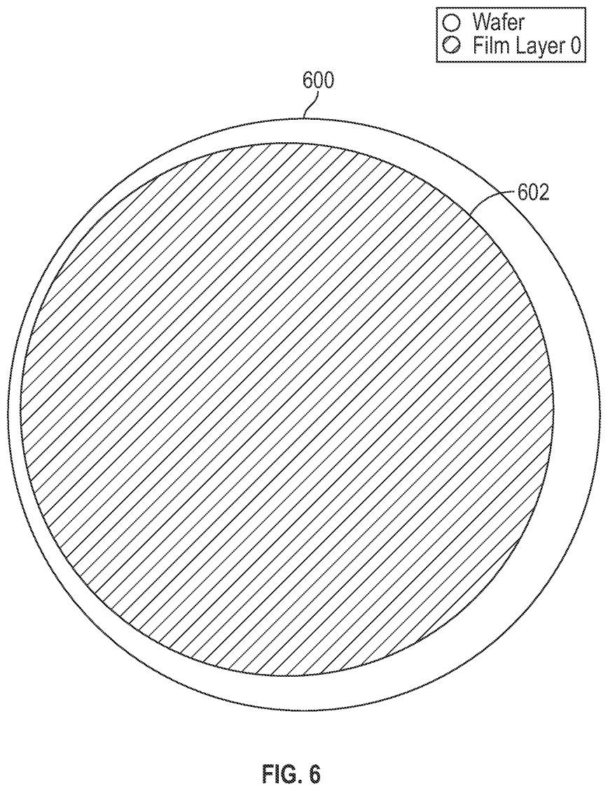

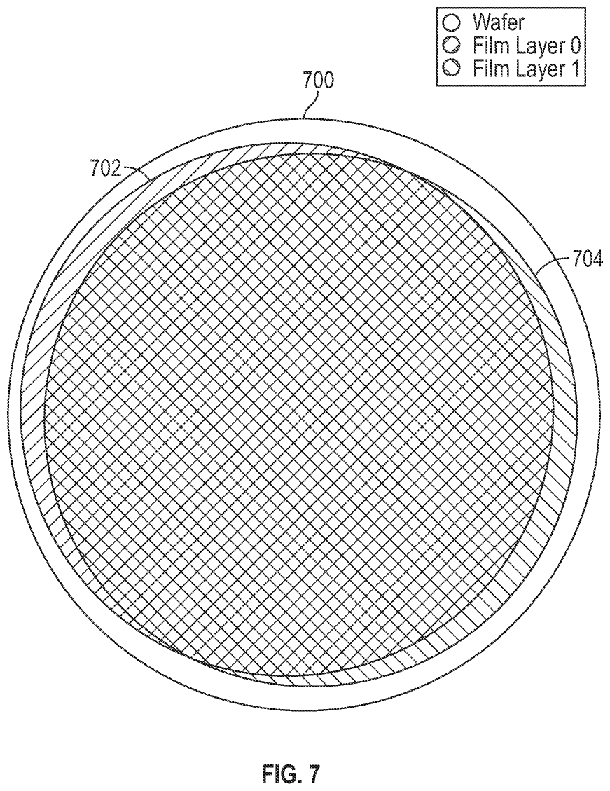

Referring now to FIG. 6, a semiconductor wafer 600 is shown as well as first film layer 602 disposed on top of the semiconductor wafer. This example represents the deviation of the curve between a single film layer and the semiconductor wafer 600 which may partially be due to spin coating of various materials and subsequent edge bead removal (EBR) processes. FIG. 7 illustrates the semiconductor wafer 700 with two film layers. A first film layer 702 and a second film layer 704 as an example of multiple spin coat operations that result in stacks of eccentric layers. In practice, the semiconductor wafer may include hundreds of film layers during the spin coat processes with different eccentricities.

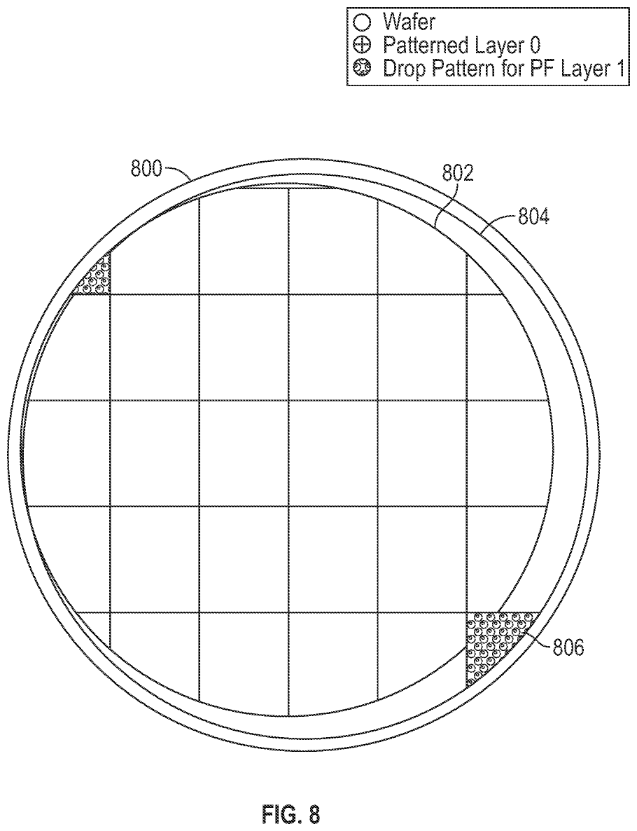

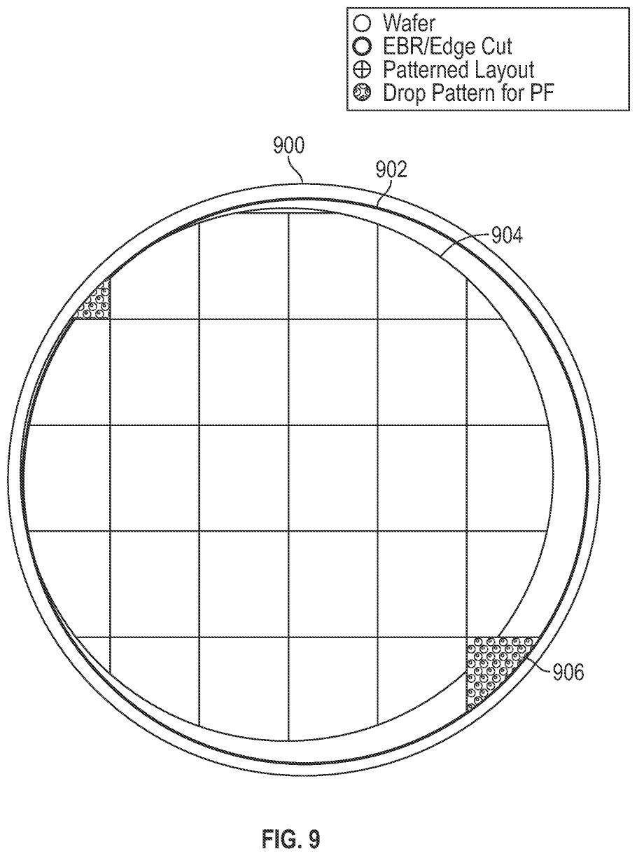

Referring now to FIG. 8, the semiconductor wafer 800 is shown with a patterned layer 802 onto which jet and flash imprint lithography (JFIL) is to be used to form another patterned layer 804. A cropped drop pattern 806 is also shown for the partial field associated with the two patterned layers (802, 804). FIG. 9 illustrates the semiconductor wafer 900 with the patterned layout 904, and an edge bead removal (EBR) or edge cut 902. The edge cut 902 has some eccentricity with respect to the semiconductor wafer edge. The patterned layout 904 has a different eccentricity with respect to the semiconductor wafer edge. The present disclosure is directed to generate a partial field drop pattern 906 that accounts for difference in centers of the edge cut 902 and the patterned layout 904. The partial field drops will fill to the edge of the edge cut 906 but preferably not extend beyond it.

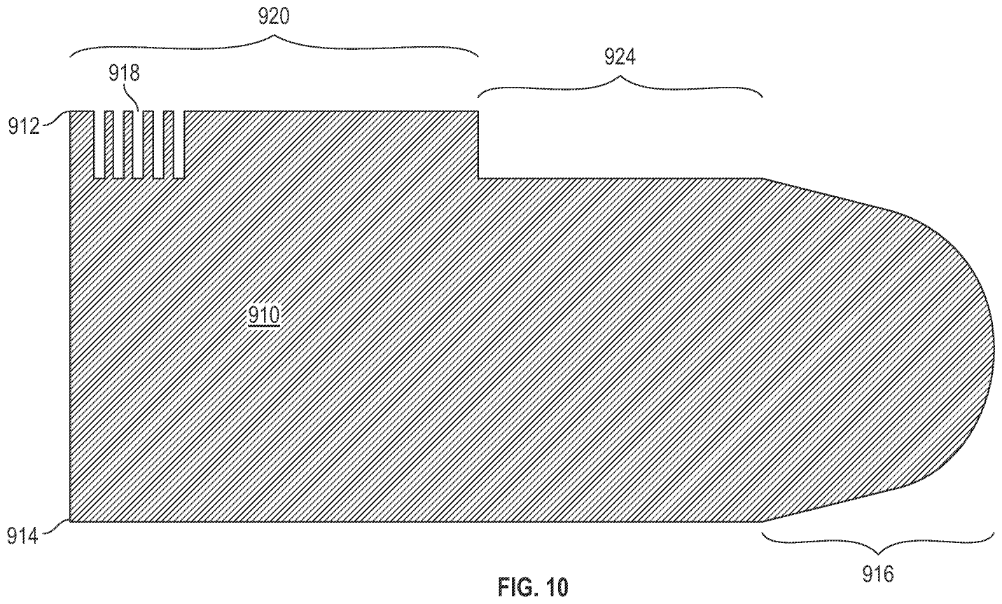

Referring now to FIG. 10, a zoomed-in side view of the wafer is shown to illustrate the edge bead removal (EBR) process. The wafer 910 includes a front surface 912, a back surface 914 and a bevel region 916. Resist is applied to the front surface 912 of the wafer 910. Edge bead can form near the wafer edge. The resist may wrap around the bevel under the wafer 910. This can contaminate tools and is undesirable. The bevel region 916 is cleaned during EBR. The zoomed in view of the wafer 910 includes etched features 918, a plateau 920 and the edge cut 922. The plateau 920 represents the initial layer where the first patterning is done on the wafer 910. All subsequent layers are aligned to the initial layer. As previously stated, photoresist is spin-coated onto the wafer 910, during spin coating, the resist can bead up and wrap around the bevel region 916. An edge bead removal operation is used to remove the undesirable resist from the bevel and backside edge of the wafer 910. Typically, this is a wafer edge solvent rinse while the wafer is spinning. The initial layer pattern is exposed and developed, then dry etched. Photoresist is removed via an ash and clean process to finish the initial layer wafer production. The edge cut defines the edge between the plateau 920 and basin 924. The basin 924 is typically the same depth as the initial layer etched features.

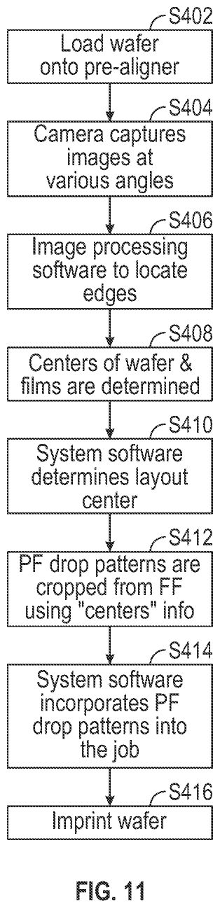

Referring now to FIG. 11, a flow chart illustrating the steps for imprinting the substrate or semiconductor wafer is shown. The first step S402 according to the present disclosure includes loading the wafer onto the pre-aligner. After loading the semiconductor wafer onto the pre-aligner, the pre-aligner begins to rotate and in step S404, the line scan camera captures images at various angles. The pre-aligner measures orientation and center. For the film layer on the wafer, it may be preferable to capture at least 4 images at various angles for determining the center of the edge cut. Completion of step S404 results in the compilation of data for determining the center of the semiconductor wafer and film as well as the edges. The sensor 502 may use dark-field microscopy illumination techniques to identify the edge cut 902.

Next, in step S406, image processing software is used by taking the data accumulated from step S404, to locate the edges of the semiconductor wafer and the film. The wafer edge can be found using an edge detection process (using for example a Sobel edge detection process; Canny edge detection process; Prewitt edge detection process; Roberts edge detection process; or fuzzy logic edge detection process). The Physical coordinates of edge pixels in the images can be calculated using an angular velocity of the semiconductor wafer spinning on the auto-aligner and data acquisition rate (which may be related to a strobe rate of an illumination source) of the camera inspecting the wafer edge. Physical coordinates of edge coordinates are fitted to the shape of the semiconductor wafer for example an ellipse (under some circumstances the ellipse may be assumed to be a circle). To find the edge of the substrate the fit is performed twice. During the first time all of the edge points are included and fitted to one of a circle or an ellipse. The alignment feature notch or flat will have a completely different radius than the rest of the edge and have a higher residual error. The location of the alignment features is calculated based on one or both of the high residual value of the fit or a radius that is threshold above the average radius. The second time, the points that represent the region around the location of the alignment feature are identified using the data from the first fit and removed for the second fit. In the case of the fit result being for an ellipse, the fit results include x and y coordinates of the wafer edge ellipse center, wafer edge the semi-major axis, wafer edge semi-minor axis, the wafer edge eccentricity and the angle between the wafer edge major axis and the horizontal axis. In the case of the fit result being for a circle the fit results include the wafer edge radius and the wafer edge center coordinates. To find the layer edge, the side of the image that includes the substrate edge calculated in the second fit is masked out to completely remove the edge of the substrate from the image. The image is then filtered in the tangential direction (along the circumference of the edge detected in the second fit). In order to find the location of the layer edge to the accuracy needed for NIL and IAP it is necessary to reduce the impact of markings, streets, etc. along the perimeter of the layer edge. The layer edge is also detected using an edge detection process (using for example a Sobel edge detection process; Canny edge detection process; Prewitt edge detection process; Roberts edge detection process; or fuzzy logic edge detection process). The coordinates of the layer edge pixels are calculated using the angular velocity and data acquisition rate (which may be related to strobe rate of an illumination source) of the camera. The physical coordinates of the layer edge pixel coordinates estimated above are fitted to an ellipse. The fitting parameters include the x and y coordinates of the ellipse center, the semi-major axis, semi-minor axis, the eccentricity and the angle between the major axis, semi-minor axis, the eccentricity and the angle between the major axis and the horizontal axis. A fitting method (such as least squares or maximum entropy) are used to estimate the fitting parameters of the layer edge. An analysis of the images may also be used to identify the field positions on the substrate.

In step S408, the centers of the semiconductor wafer and film(s) are determined using the edges that were located in step S406. Then in step S410, the system software is utilized to determine the layout center of a full field in an initial contact point or the plurality of layout centers in partial fields for nanoimprint lithography.

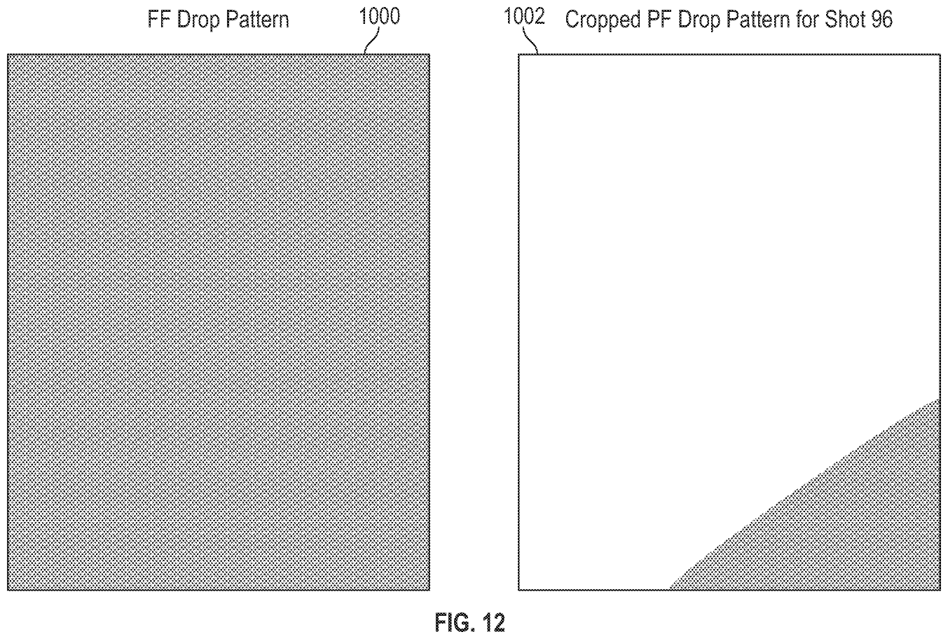

In step S412, partial field (PF) drop patterns are cropped from full field (FF) using the layout center information determined in step S410. FIG. 12 illustrates a full field drop pattern 1000 and a cropped partial field drop pattern 1002 for partial field 96 in FIG. 4. Referring back to FIG. 4, fields 21-28, 32-41, 44-53, 56-65, 69-76 and 81-86 are examples of full fields in which a full field drop pattern is applied as shown in FIG. 12. The remaining fields from FIG. 4 are considered partial fields because they are located at the perimeter of the semiconductor wafer. For the partial fields, a cropped partial field drop pattern is applied in accordance with the present disclosure. In particular, FIG. 12 shows a representation of partial field 96 and the partial field drop pattern that is to be applied. It is important to note that the partial field drop pattern is applied to a region within the interior of the perimeter of the semiconductor wafer. It is preferable to keep the fluid from being applied at the exterior of the perimeter on the partial field.

Referring back to FIG. 11, after the partial field drop patterns are cropped from the full field in step S412 using the layout center information, in the next step S414, the system software incorporates the partial field drop pattern for all the partial fields of the semiconductor wafer or one full wafer field in the case of inkjet-based adaptive planarization in which the whole wafer is planarized at one time. Then in step S416, the individual full and partial fields of the semiconductor wafer are imprinted accordingly in series or all at once in the case of inkjet-based adaptive planarization. Both the image processing software and the system software may be executed by the one or more processors 140 (controller). The software may be executed at the pre-aligner or remotely via a network or Internet communication.

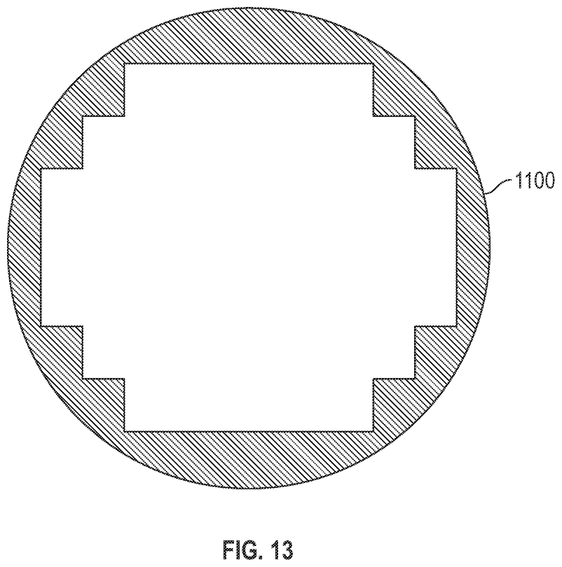

FIG. 13 illustrates an example of the partial field pattern result 1100 of the semiconductor wafer from FIG. 4 when all of the partial fields are generated together. The patterns may be created using a high level programming language, for example a TCL script from a graphic user interface by way of example and not limitation. Other known scripts may be used to generate the patterns based on data accumulated in steps S402-S410. FIG. 13 shows all the partial fields plotted on the semiconductor wafer for reference.

The above-described exemplary embodiments are merely specific examples for carrying out the present disclosure. The technical scope of the present disclosure should not be interpreted in a limited way due to these embodiments. The present disclosure can be carried out in various forms without departing from the technical idea or the main features thereof. For example, any combination of the exemplary embodiments is also included in the disclosed contents of the present disclosure.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method of determining a boundary of a substrate on a pre-aligner, the method comprising:
loading the substrate with a film onto the pre-aligner;
measuring a substrate edge of the substrate;
determining a substrate center of the substrate based on the substrate edge;
measuring a film edge of the film on the substrate; and
determining a film edge shape of the film edge relative to the substrate center based on the measurements of the film edge.

2. The method of claim 1, wherein the substrate is a semiconductor wafer.

3. The method of claim 1, further comprising determining a layout center of a field to be imprinted on the substrate based on the measured substrate edge.

4. The method of claim 1, wherein the substrate edge is measured relative to a notch on the pre-aligner.

5. The method of claim 1, further comprising:
a sensor for measuring the substrate edge of the substrate and the film edge while the substrate is rotating on the pre-aligner.

6. The method of claim 5, wherein the sensor is a camera for capturing images while the substrate is rotating on the pre-aligner.

7. The method of claim 6, wherein the camera captures a plurality of images for determining at least four locations that are equidistant from the layout center to determine the substrate edge.

8. The method of claim 6, wherein the camera captures a plurality of images for determining at least twelve locations to determine the film edge.

9. The method of claim 1, wherein the substrate edge is measured with a plurality of coordinates using a least squares approximation.

10. The method of claim 1, wherein the film on the substrate is formed by removing material from the film in an edge bead removal (EBR) process to form the edge of the film.

11. The method of claim 1, wherein the film edge is measured with a plurality of coordinates using a least squares approximation.

12. The method of claim 1, further comprising:
generating a partial field drop pattern based on the film edge shape; and
depositing the partial field drop pattern on a partial field of the substrate.

13. The method of claim 12, wherein the partial field drop pattern is deposited on the partial field to fill up to the edge of the film without extending beyond the edge of the film.

14. The method of claim 1, further comprising:
manufacturing one or more articles, wherein manufacturing the one or more articles includes:
depositing drops of formable material on the substrate according to a partial field drop pattern;
bringing a shaping surface of one of a superstrate and a template into contact with the formable material that has been deposited on the substrate;
after bringing the shaping surface into contact with a fluid that has been deposited on the substrate, curing the formable material that has been deposited on the substrate; and
after curing the formable material that has been deposited on the substrate, processing the substrate so as to manufacture the one or more articles.

15. A semiconductor wafer pre-aligner comprising:
a semiconductor wafer rotation stage;
an edge detection system configured to measure a semiconductor wafer edge of a semiconductor wafer loaded onto the semiconductor wafer rotation stage; and
a film edge detection system configured to measure a film edge of a film on the semiconductor wafer loaded onto the semiconductor wafer rotation stage while the edge detection system measures the semiconductor wafer edge.

16. The semiconductor wafer pre-aligner of claim 15, wherein the edge detection system includes a laser edge detector that obtains a semiconductor wafer location of the semiconductor wafer edge, wherein the film edge detection includes a camera for obtaining images of a film edge on a semiconductor wafer loaded onto the semiconductor wafer rotation system.

17. A semiconductor wafer pre-aligner device for drop-pattern generation, the device comprising:
one or more computer-readable storage media; and
one or more processors that are in communication with the one or more computer-readable storage media and that cooperate with the one or more computer-readable storage media to cause the device to perform operations comprising:
loading a semiconductor wafer with a film onto the semiconductor wafer pre-aligner;
measuring a semiconductor wafer edge of the semiconductor wafer;
determining a layout center of a field to be imprinted on the semiconductor wafer based on the measured semiconductor wafer edge;
measuring a film edge of the film on the semiconductor wafer; and
determining a film edge shape of the film edge relative to the layout center based on the measurements of the film edge.

18. The semiconductor wafer pre-aligner of claim 15, wherein:
the edge detection system comprises:
a first light source that produces a first measurement light and a first sensor that receives the first measurement light;
the film edge detection system comprises:
a second light source that produces a second measurement light and a second sensor that receives the second measurement light;
the first sensor is positioned such that the second measurement light detected by the first sensor is less than 1% of the first measurement light detected by the first sensor; and
the second sensor is positioned such that the first measurement light detected by the second sensor is less than 1% of the second measurement light detected by the second sensor.

19. The method of claim 4, wherein the film edge is measured at the same time that the wafer notch is determined.
